(19) United States
(12) Patent Application Publication
(10) Pub. No.: US 2007/0254399 A1
(43) Pub. Date: Nov. 1, 2007

(54) LOW TEMPERATURE DIRECT DEPOSITED POLYCRYSTALLINE SILICON THIN FILM TRANSISTOR STRUCTURE AND METHOD FOR MANUFACTURING THE SAME

(75) Inventors: Min Chuan WANG, Chiayi City (TW); I-Hsuan PENG, Hsinchu County (TW); Te-Chi WONG, Sinying City (TW); Liang-Tang WANG, Tainan City (TW); Chin-Jen HUANG, Kaohsiung City (TW)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Industrial Technology Research Institute, Hsinchu (TW)

(21) Appl. No.: 11/380,491

(22) Filed: Apr. 27, 2006

(51) Int. Cl. H01L 21/00; H01L 21/84

(52) U.S. Cl. 438/62; 438/149; 257/223

(57) ABSTRACT

A method for manufacturing a thin film transistor (“TFT”) device includes providing a substrate, forming a patterned first metal layer on the substrate, forming an insulating layer over the patterned first metal layer, forming an amorphous silicon layer over the insulating layer, forming a first polycrystalline silicon layer over the amorphous silicon layer, forming a second polycrystalline silicon layer over the first polycrystalline silicon layer, doping the second polycrystalline silicon layer to form a doped polycrystalline silicon layer, patterning the amorphous silicon layer, first polycrystalline silicon layer and doped polycrystalline silicon layer to form an active region layer for the TFT device, and forming a patterned second metal layer over the active region layer.

### BACKGROUND OF THE INVENTION

The present invention relates generally to thin film transistors (“TFTs”), and more particularly, to a low temperature polycrystalline silicon (“LTPS”) TFT structure and a method for fabricating the same.

In flat display devices such as liquid crystal display (“LCD”) devices, organic electroluminescence display devices and inorganic electroluminescence display devices, a thin film transistor (“TFT”) is generally used as a switching device for controlling operations of pixels or used as a driving device for driving the pixels.

The TFT is usually classified as an amorphous silicon (a-Si) type or a polycrystalline silicon (poly-Si) type. A poly-Si TFT has much higher mobility resulting in better crystal character, fewer crystal defects and smaller photo leakage current increase as compared to an a-Si TFT. Therefore, displays fabricated from poly-Si TFT have advantages of high resolution, high response speed and integrated driver circuits. However, there are some drawbacks to poly-Si TFTs such as low product yield, complex processes, and high process cost. A conventional method for fabricating poly-Si films is excimer laser annealing (“ELA”), which has the disadvantages of the high cost for laser light, process instability and poor crystal uniformity. In contrast, a-Si TFTs are fabricated using well-developed techniques having a lower process cost but also lower image quality.

With the progress in semiconductor manufacturing techniques, the panel size of flat panel display devices has been rapidly increasing. A large-size, high-resolution a-Si LCD TV is generally required to have a brightness level of at least approximately 450 cd/M² (or nits), which in turn requires a light source that provides a greater illumination level. However, the greater illumination level may incur a greater leakage current, which adversely affects the display quality of the TV. It is therefore desirable to have a method for manufacturing a TFT device that has lower photo leakage current at a lower manufacturing cost without compromising any display quality.

### BRIEF SUMMARY OF THE INVENTION

The present invention is directed to a method for manufacturing thin film transistor (“TFT”) devices including dual polycrystalline silicon layers that obviate one or more problems resulting from the limitations and disadvantages of the prior art.

In accordance with an embodiment of the present invention, there is provided a method for manufacturing a thin film transistor (“TFT”) device that comprises providing a substrate, forming a patterned first metal layer on the substrate, forming an insulating layer over the patterned first metal layer, forming an amorphous silicon layer over the insulating layer, forming a first polycrystalline silicon layer over the amorphous silicon layer, forming a second polycrystalline silicon layer over the first polycrystalline silicon layer, doping the second polycrystalline silicon layer to form a doped polycrystalline silicon layer, patterning the amorphous silicon layer, first polycrystalline silicon layer and doped polycrystalline silicon layer to form an active region layer for the TFT device, and forming a patterned second metal layer over the active region layer.

Also in accordance with the present invention, there is provided a method for manufacturing a TFT device that comprises providing a substrate, forming a patterned first metal layer on the substrate, forming an insulating layer over the patterned first metal layer, forming an amorphous silicon layer over the insulating layer, forming a polycrystalline silicon layer over the amorphous silicon layer, forming a doped polycrystalline silicon layer over the polycrystalline silicon layer, forming a patterned second metal layer over the doped polycrystalline silicon layer, exposing a portion of the doped polycrystalline silicon layer, and patterning the amorphous silicon layer, polycrystalline silicon layer and doped polycrystalline silicon layer.

Further in accordance with the present invention, there is provided a semiconductor device that comprises a substrate, a patterned first metal layer formed on the substrate, an insulating layer formed over the patterned first metal layer, a patterned amorphous silicon layer formed over the insulating layer, a patterned polycrystalline silicon layer formed over the patterned amorphous silicon layer, a doped, patterned polycrystalline silicon layer formed over the patterned polycrystalline silicon layer, and a patterned second metal layer formed over the doped, patterned polycrystalline silicon layer.

Additional features and advantages of the present invention will be set forth in portion in the description which follows, and in portion will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIGS. 1A to 1E are diagrams illustrating a method of fabricating a thin film transistor (“TFT”) in accordance with a first embodiment of the present invention;

FIGS. 2A to 2D are diagrams illustrating a method of fabricating a TFT in accordance with a second embodiment of the present invention; and

FIGS. 3A and 3B are plots illustrating experiment results.

### DETAILED DESCRIPTION OF THE INVENTION

Reference will now be made in detail to the present embodiments of the invention, examples of which are illustrated in the accompanying drawings. Wherever possible, the same reference numbers will be used throughout the drawings to refer to the same or like portions.

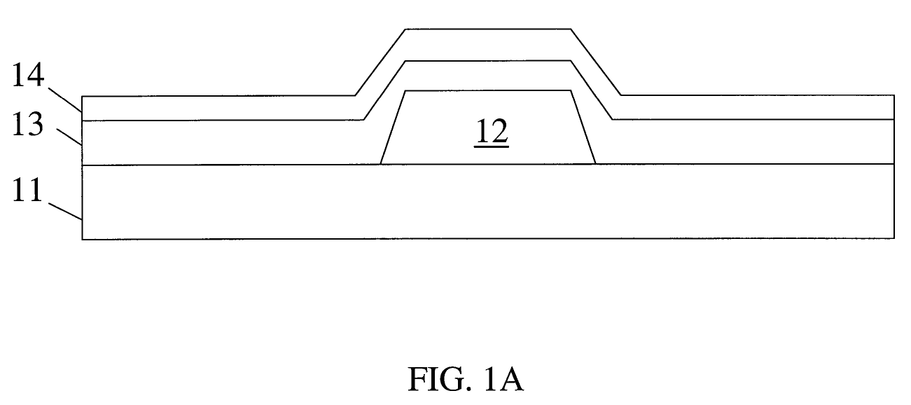

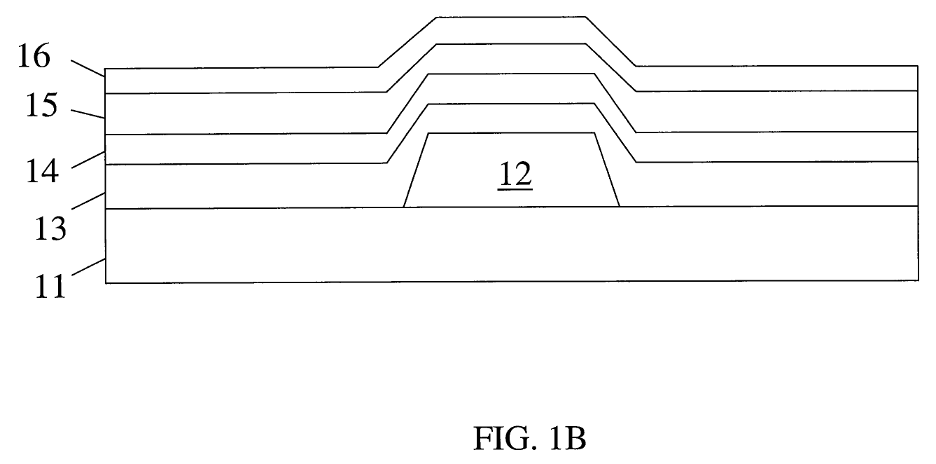

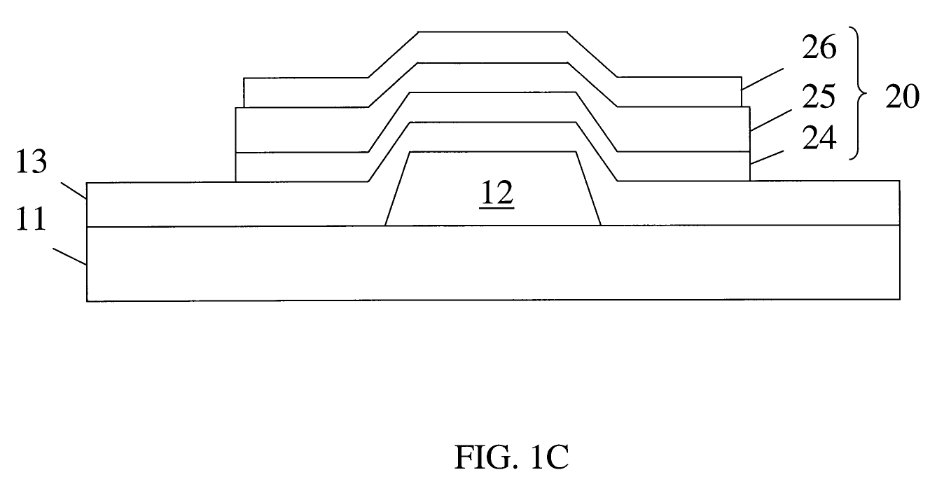

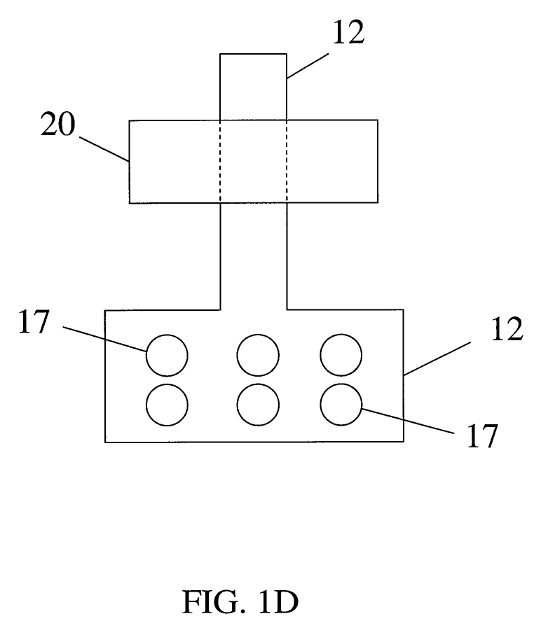

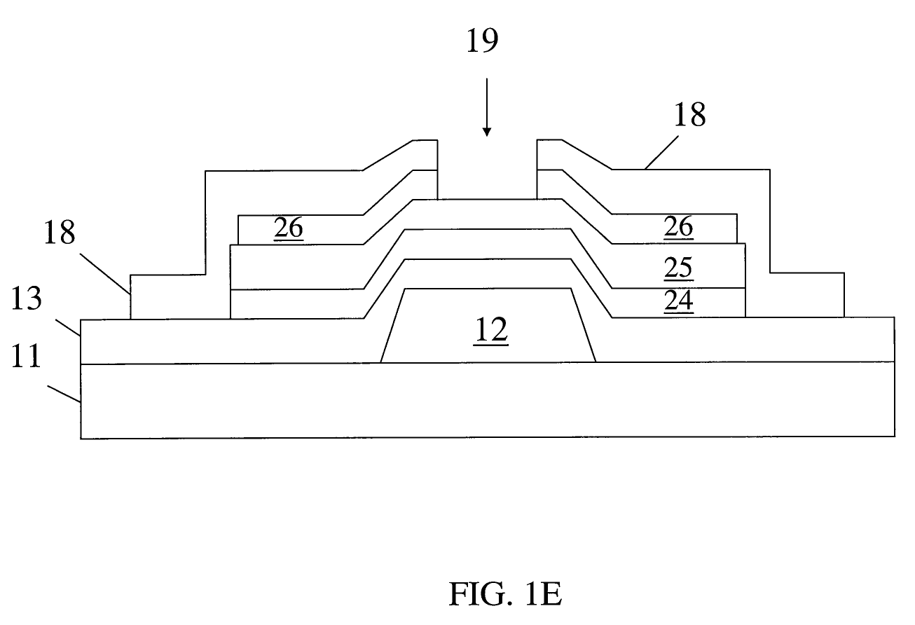

FIGS. 1A to 1E are diagrams illustrating a method of fabricating a thin film transistor (“TFT”) in accordance with a first embodiment of the present invention. Referring to FIG. 1A, a schematic cross-sectional view of the TFT being fabricated, a substrate 11, made of glass or resin, for example, is provided. Preferably the thickness of the substrate 11 ranges from approximately 0.3 to 0.7 mm (millimeter) but could be thinner or thicker. Next, a patterned first metal layer 12 is formed on the substrate 11 by forming a layer of a first metal on the substrate 11 by a conventional physical vapor deposition (“PVD”) process, sputtering or some other suitable process, and then patterning the layer of first metal by a conventional patterning process such as photolithography and etching. The first metal is a material with good electric conductivity such as copper (Cu), chromium (Cr), molybdenum (Mo), moly-tungsten (MoW), TiAlTi, MoAlMo and CrAlCr. Preferably, the thickness of the patterned first metal layer 12 ranges from approximately 2000 to 3000 Å (angstrom) but could be some other thickness. The patterned first metal layer 12 serves as a gate electrode of the TFT being fabricated.

Next, an insulating layer 13 is formed on the patterned first metal layer 12 by, for example, a conventional chemical vapor deposition (“CVD”) process such as a plasma-enhanced CVD (“PECVD”) process or some other suitable process. Suitable materials for the insulating layer 13 include silicon nitride, silicon oxide and silicon oxynitride. Preferably, the thickness of the insulating layer 13 ranges from approximately 3000 to 4500 Å.

Next, an amorphous silicon layer 14 is formed over the insulating layer 13 by, for example, a conventional CVD process such as a PECVD process or some other suitable process. In the first embodiment according to the present invention, the insulating layer 13 and amorphous silicon layer 14 are formed successively in the same chamber, i.e., in situ, during the PECVD process. Preferably, the thickness of the amorphous silicon layer 14 ranges from approximately 300 to 500 Å.

Referring to FIG. 1B, a polycrystalline silicon layer 15 and a doped polycrystalline silicon layer 16 are formed over the amorphous silicon layer 14. The polycrystalline silicon layer 15 is formed by, for example, a conventional high density plasma CVD (“HDPCVD”) process such as electron cyclotron resonance (“ECR”) CVD or inductively coupled plasma (“ICP”) CVD by depositing a first layer of polycrystalline silicon over the amorphous silicon layer 14. The doped polycrystalline silicon layer 16, which may include intrinsic-doped polycrystalline silicon, is formed by, for example, a conventional HDPCVD process by depositing a second layer of polycrystalline silicon over the polycrystalline silicon layer 15 while providing a gaseous dopant such as phosphine (PH₃) gas to dope the second layer of polycrystalline silicon during deposition. In the first embodiment according to the present invention, the polycrystalline silicon layer 15 and the doped polycrystalline silicon layer 16 are formed successively in the same chamber, i.e., in situ, during an HDPCVD process. Preferably, the concentration of the doped polycrystalline silicon layer 16 ranges from approximately 10²⁰ to 10²¹ cm⁻³.

Referring to FIG. 1C, subsequent to the deposition of the polycrystalline silicon layer 15 and doped polycrystalline silicon layer 16, an active region 20 of the TFT being fabricated is defined by, for example, a conventional patterning process such as photolithography and etching. The active region 20 includes a patterned amorphous silicon layer 24, a patterned polycrystalline silicon layer 25 and a patterned, doped polycrystalline silicon layer 26. Preferably, the thickness of the patterned amorphous silicon layer 24 ranges from approximately 300 to 500 Å but could be some other thickness. The thickness of the patterned polycrystalline silicon layer 25 ranges from approximately 1000 to 1500 Å but could be some other thickness. The thickness of the patterned, doped polycrystalline silicon layer 26 ranges from approximately 300 to 500 Å but could be some other thickness.

Next, referring to FIG. 1D, there is shown a schematic top plan view of the TFT shown in FIG. 1C being fabricated., A plurality of contact holes 17 are formed by, for example, a conventional patterning process such as photolithography and etching, exposing portions of the patterned first metal layer 12. The exposed portions of the patterned first metal layer 12 communicate a later formed second metal layer through the plurality of contact holes 17. Preferably, the diameter of each of the plurality of contact holes 17 is approximately 5 μm (micrometer) but could be some other size.

Next, referring to FIG. 1E, a patterned second metal layer 18 is formed by forming a layer of second metal over the active region 20 by a conventional PVD process, sputtering or some other suitable process, and then patterning the layer of second metal 18 by a conventional patterning process such as photolithography and etching, exposing a portion of the patterned, doped polycrystalline silicon layer 26 through an opening 19. The exposed portion of the patterned, doped polycrystalline silicon layer 26 is then removed by a conventional etching process, using the patterned second metal layer 18 as a mask, which exposes a portion of the patterned polycrystalline silicon layer 25. The exposed portion of the patterned polycrystalline silicon layer 25 in the opening 19 defines a channel region of the TFT being fabricated. The second metal is a material with good electric conductivity, which includes but is not limited to Cu, Cr, Mo, MoW, TiAlTi, MoAlMo and CrAlCr. Preferably, the thickness of the patterned second metal layer 18 is approximately 3000 Å but could be some other thickness. The patterned second metal layer 18 serves as a source/drain pair for the TFT being fabricated.

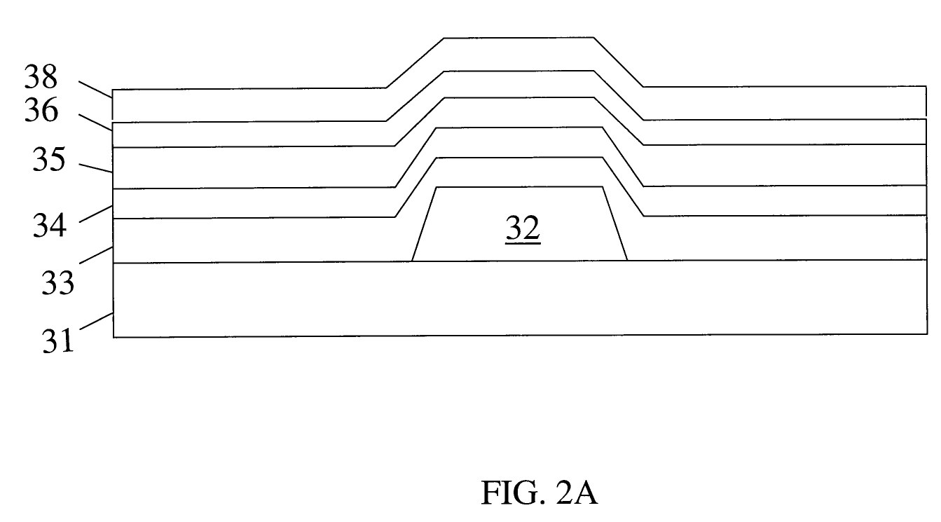

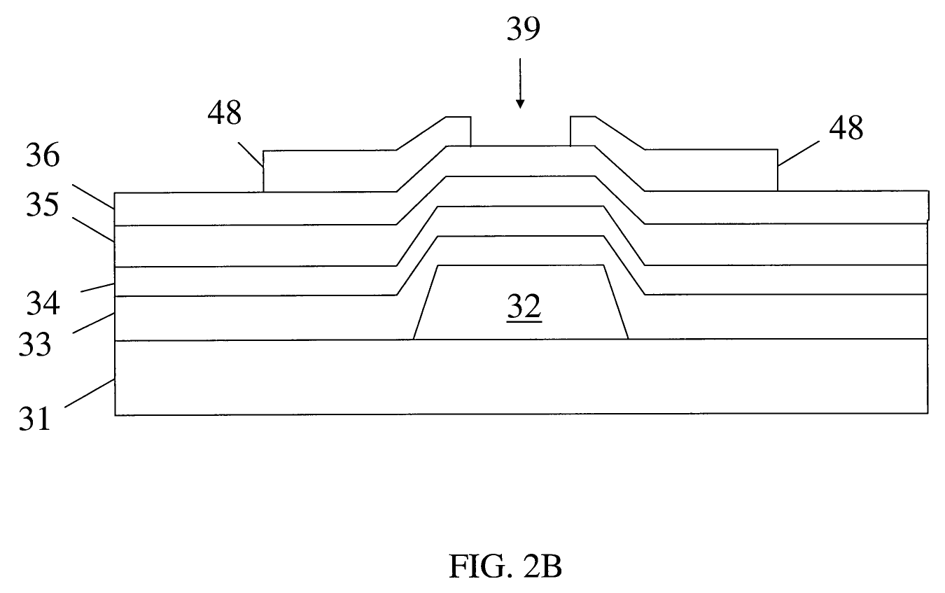

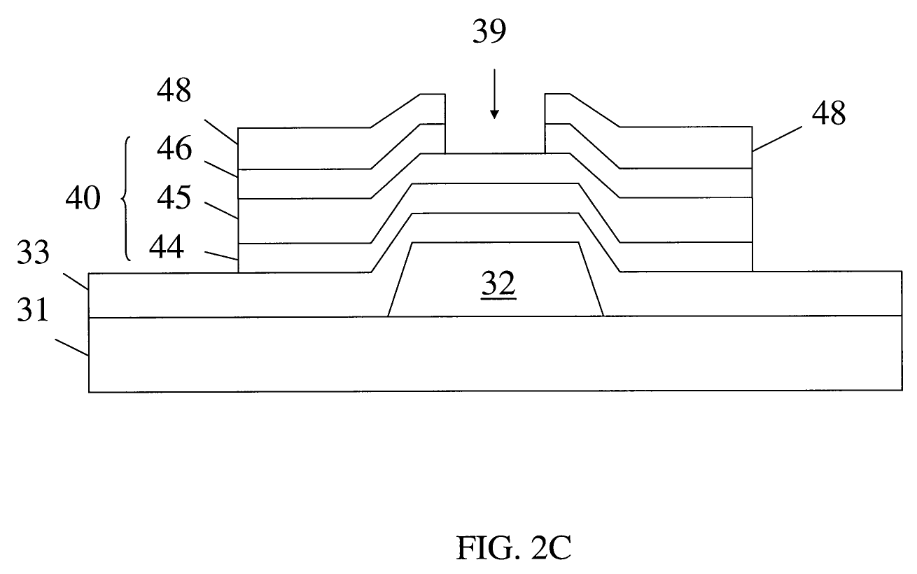

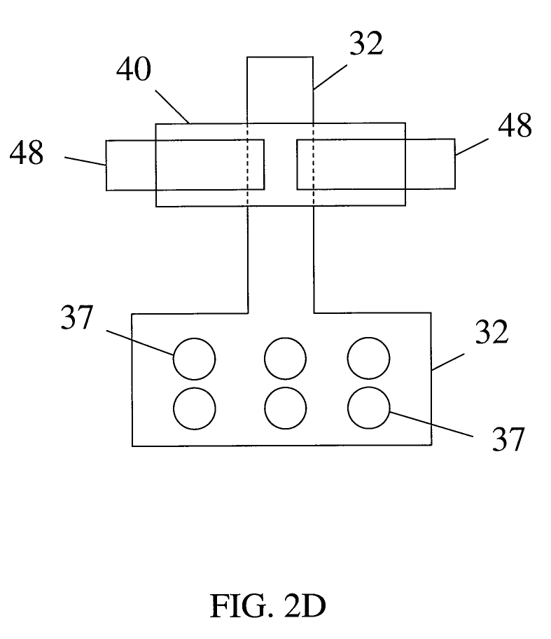

FIGS. 2A to 2D are diagrams illustrating a method of fabricating a TFT in accordance with a second embodiment of the present invention. Referring to FIG. 2A, a schematic cross-sectional view of the TFT being fabricated, a substrate 31, made of glass or resin, is provided. Next, a patterned first metal layer 32, an insulating layer 33 and an amorphous silicon layer 34 are formed over the substrate 31 in turn. In the second embodiment according to the present invention, the insulating layer 33 and amorphous silicon layer 34 are formed successively in the same chamber, i.e., in situ, during a PECVD process. Next, a polycrystalline silicon layer 35, a doped polycrystalline silicon layer 36 and a second metal layer 38 are formed, in turn, over the amorphous silicon layer 34. The processes for forming the patterned first metal layer 32, insulating layer 33, amorphous silicon layer 34, polycrystalline silicon layer 35, doped polycrystalline silicon layer 36 and second metal layer 38 are similar to those described by reference to FIGS. 1A, 1B and 1E and are therefore not discussed.

Referring to FIG.2B, a patterned second metal layer 48 is formed by patterning the second metal layer 38 by a conventional patterning process such as photolithography and etching, exposing a portion of the doped polycrystalline silicon layer 36 through an opening 39.

Next, referring to FIG. 2C, an active region 40 of the TFT being fabricated is defined by, for example, a conventional patterning process such as photolithography and etching, using the patterned second metal layer 48 as a mask. The active region 40 includes a patterned amorphous silicon layer 44, a patterned polycrystalline silicon layer 45 and a patterned, doped polycrystalline silicon layer 46. A portion of the patterned polycrystalline silicon layer 45 is exposed through the opening 39.

Next, referring to FIG. 2D, there is shown a schematic top plan view of the TFT being fabricated shown in FIG. 2C. A plurality of contact holes 37 are formed by, for example, by a conventional patterning process such as photolithography and etching, exposing portions of the patterned first metal layer 32. The exposed portions of the patterned first metal layer 32 communicate the patterned second metal layer 48 through the plurality of contact holes 37.

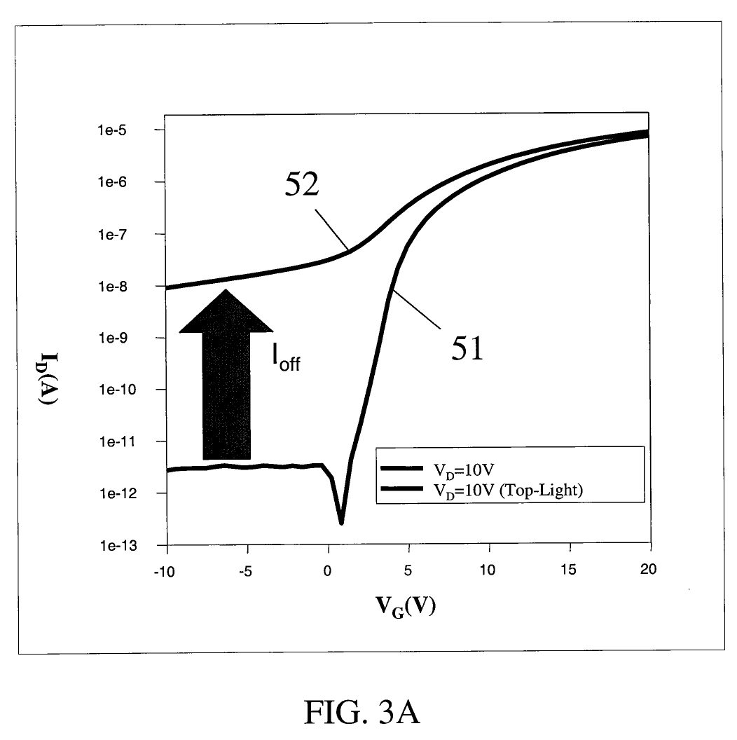

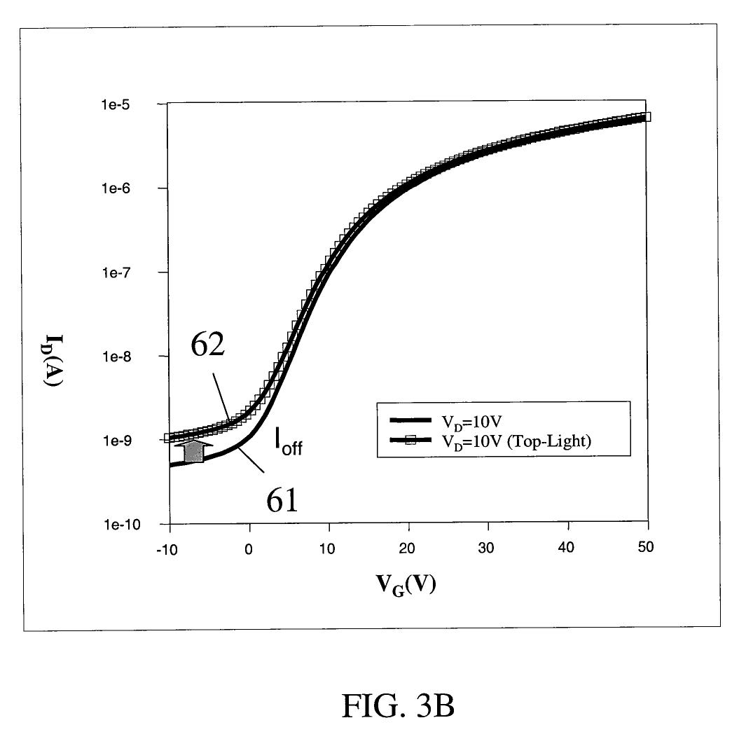

FIGS. 3A and 3B are plots illustrating experiment results. FIG. 3A shows the experiment results of a conventional TFT device. The conventional TFT device has a similar structure to the TFT according to the present invention illustrated in, for example, FIG. 1E, except: (1) that the amorphous silicon layer of the conventional TFT is approximately 2000 Å compared to 300 to 500 Å for the present invention and (2) the present invention has a patterned, doped polycrystalline silicon layer 26 while a conventional TFT lacks the patterned doped polycrystalline layer 2. Referring to FIG. 3A, curves 51 and 52 represent the level of leakage current I_{OFF} before and after a front-side illumination, respectively. In general, a front-side illumination, where light travels from the source/drain toward the gate side of a TFT, incurs a larger leakage current in the TFT than a back-side illumination, where light travels from the gate toward the source-drain side of the TFT. Given a front-side illumination of approximately 3300 nits and the conventional TFT being kept at an off state (V_{G}=0), the leakage current I_{OFF} of the curve 52 is approximately 4 orders greater than that of the curve 51 when V_{G} is equal to or smaller than zero.

FIG. 3B shows the experimental results of a TFT device in accordance with the first embodiment of the present invention. Referring to FIG. 3B, curves 61 and 62 represent the level of leakage current I_{OFF} before and after a front-side illumination, respectively. Given a front-side illumination of approximately 3300 nits from a tungsten lamp and the TFT being kept at an off state (V_{G}=0), the leakage current I_{OFF} of the curve 62 increases by less than one order of magnitude as compared to that of the curve 61 when V_{G} is equal to or smaller than zero. That is, by a comparison between the results show in FIGS. 3A and 3B, the TFT device according to the present invention has a lower photo leakage current after front side illumination than the conventional TFT device.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

I/we claim:

1. A method for manufacturing a thin film transistor (“TFT”) device, comprising:
providing a substrate;
forming a patterned first metal layer on the substrate;
forming an insulating layer over the patterned first metal layer;
forming an amorphous silicon layer over the insulating layer;
forming a first polycrystalline silicon layer over the amorphous silicon layer;
forming a second polycrystalline silicon layer over the first polycrystalline silicon layer;
doping the second polycrystalline silicon layer to form a doped polycrystalline silicon layer;
patterning the amorphous silicon layer, first polycrystalline silicon layer and doped polycrystalline silicon layer to form an active region layer for the TFT device; and
forming a patterned second metal layer over the active region layer.

2. The method of claim 1, further comprising exposing a portion of the doped polycrystalline silicon layer in forming the patterned second metal layer over the active region layer.

3. The method of claim 2, further comprising exposing a portion of the first polycrystalline silicon layer.

4. The method of claim 1, further comprising forming a plurality of contact holes in the patterned first metal layer after forming the active region layer.

5. The method of claim 1, further comprising forming the insulating layer and the amorphous silicon layer in situ.

6. The method of claim 1, further comprising forming the first polycrystalline silicon layer and the second polycrystalline silicon layer in situ.

7. The method of claim 1, further comprising forming the first polycrystalline silicon layer and the doped polycrystalline silicon layer in situ.

8. The method of claim 1, further comprising forming the first polycrystalline layer and the second polycrystalline silicon layer by a high density plasma chemical vapor deposition (“HDPCVD”) process.

9. The method of claim 8, wherein the HDPCVD process includes one of an electron cyclotron resonance (“ECR”) CVD and an inductively coupled plasma (“ICP”) CVD.

10. A method for manufacturing a thin film transistor (“TFT”) device, comprising:
providing a substrate;
forming a patterned first metal layer on the substrate;
forming an insulating layer over the patterned first metal layer;
forming an amorphous silicon layer over the insulating layer;
forming a polycrystalline silicon layer over the amorphous silicon layer;
forming a doped polycrystalline silicon layer over the polycrystalline silicon layer;
forming a patterned second metal layer over the doped polycrystalline silicon layer; exposing a portion of the doped polycrystalline silicon layer; and
patterning the amorphous silicon layer, polycrystalline silicon layer and doped polycrystalline silicon layer.

11. The method of claim 10, further comprising exposing a portion of the polycrystalline silicon layer in patterning the amorphous silicon layer, polycrystalline silicon layer and doped polycrystalline silicon layer.

12. The method of claim 10, further comprising forming a plurality of contact holes in the patterned first metal layer.

13. The method of claim 10, further comprising forming the insulating layer and the amorphous silicon layer in situ.

14. The method of claim 10, further comprising forming the polycrystalline silicon layer and the doped polycrystalline silicon layer in situ.

15. The method of claim 10, further comprising forming the polycrystalline layer and the doped polycrystalline silicon layer in a high density plasma chemical vapor deposition (“HDPCVD”) process.

16. The method of claim 15, wherein the HDPCVD process includes one of an electron cyclotron resonance (“ECR”) CVD and an inductively coupled plasma (“ICP”) CVD.

17. A semiconductor device, comprising:
a substrate;
a patterned first metal layer formed on the substrate;
an insulating layer formed over the patterned first metal layer;
a patterned amorphous silicon layer formed over the insulating layer;
a patterned polycrystalline silicon layer formed over the patterned amorphous silicon layer;
a doped, patterned polycrystalline silicon layer formed over the patterned polycrystalline silicon layer; and
a patterned second metal layer formed over the doped, patterned polycrystalline silicon layer.

18. The device of claim 17, wherein a portion of the patterned polycrystalline silicon layer is exposed.

19. The device of claim 17, wherein the patterned amorphous silicon layer, patterned polycrystalline silicon layer and doped, patterned polycrystalline silicon layer define an active region layer for the semiconductor device.

20. The device of claim 17, further comprising a plurality of contact holes extending between the patterned first metal layer and the patterned second metal layer.
